(19) United States
(12) Patent Application Publication
(10) Pub. No.: US 2026/0367148 A1
(43) Pub. Date: Nov. 19, 2026

(54) TEST PATTERN GENERATION

(71) Applicant: SIEMENS INDUSTRY SOFTWARE INC., Plano, TX (US)

(72) Inventors: Nilanjan MUKHERJEE, Wilsonville, OR (US); Janusz RAJSKI, West Linn, OR (US); Kun-Han TSAI, Lake Oswego, OR (US); Jay WU, Wilsonville, OR (US); Hari ADDEPALLI, West Linn, OR (US); Irith POMERANZ, West Lafayette, IN (US)

(21) Appl. No.: 19/515,476

(22) PCT Filed: Aug. 31, 2023
(86) PCT No.: PCT/US2023/031665

§ 371 Date: Feb. 28, 2026

(51) Int. Cl. G01R 31/317; G01R 31/3181; G01R 31/3183

(52) U.S. Cl. CPC G01R 31/31725; G01R 31/31813; G01R 31/318307; G01R 31/318321

(57) ABSTRACT

A method and data processing system for extracting a path with a longest delay time through an integrated circuit is provided. The method includes obtaining a dataset for the integrated circuit including a maximum arrival time and a maximum propagation delay, and selecting a logical cell in the integrated circuit. The method includes identifying a longest arrival path from a start point in the integrated circuit to an output pin of the selected logical cell based on the dataset, identifying a longest propagation path from an input pin of the selected logical cell to an end point in the integrated circuit, and extracting a longest path through the selected logical cell based on the identified longest arrival path and longest propagation path.

This application is the National Stage of International Application No. PCT/US2023/031665, filed Aug. 31, 2023. The entire contents of this document are hereby incorporated herein by reference.

### TECHNICAL FIELD

The present disclosure relates to methods and systems for testing integrated circuits. Various aspects of the present embodiments may be used for cell library characterization and test pattern generation.

### BACKGROUND

In recent years, there has been increasing focus in the semiconductor industry on the disruptive impact of Silent Data Errors (SDEs), also called Silent Data Corruption (SDC), in data centers. SDEs are elusive and difficult to detect until they affect a particular application. Detection may occur several days or months after an integrated circuit (IC) has been deployed in-field. In addition, it has also been observed that the majority of such devices fail at a very early stage of their deployment, thereby raising the question regarding the reliability and quality of manufacturing tests.

Although the causes of SDEs may be manifold, ranging from test escapes and design marginalities to design bugs, there is a consensus across the industry that they are often traced back to timing delay issues. Depending on the software workloads and different operating and environmental conditions, referred to as process, voltage, and temperature (PVT) corners, the performance of transistors may vary so that some defective behavior is only captured under certain conditions. Defective behavior may also occur at a later stage of the lifetime of a chip. In this case, silicon degradation due to aging effects is manifested as additional delay related failures. For example, aging effects caused by negative bias temperature instability (NBTI), and hot carrier injection (HCI), degrade the circuit performance and raise reliability issues. In addition, the impact of aging on transistors is not uniform, making it harder to screen for SDEs.

The investigation of the root cause of SDEs, such as isolating defective cores and reverse engineering, is complex and costly. There is therefore an urgent need for improved test generation and design-for-test (DFT) techniques, such that timing-related defects that cause SDEs may be detected before the defective chips are shipped and deployed. The impact of different environmental conditions and lifetime degradation on cell propagation delays is also to be considered during test generation.

Timing related defects may be targeted in at least two ways. A first class of test generation procedures detect a small delay fault by propagating a transition through the fault site using the longest possible path. For example, the timing-aware cell-aware-test (TA CAT) Automatic Test Pattern Generation (ATPG) generates tests for small delay defects by propagating transitions through long paths with minimal slack. A second class of test generation procedures use various criteria for selecting a subset of the longest path delay faults directly as targets for test generation.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a method for test pattern generation is provided.

According to a first aspect, a method for extracting a path with a longest delay time through an integrated circuit is provided. The method includes a) obtaining a dataset for the integrated circuit. The dataset includes a maximum arrival time and a maximum propagation delay for each pin in the integrated circuit. The method includes b) selecting a logical cell in the integrated circuit, c) identifying a longest arrival path from a start point in the integrated circuit to an output pin, O, of the selected logical cell based on the dataset, and d) identifying a longest propagation path from an input pin, I, of the selected logical cell to an end point in the integrated circuit. The method also includes e) extracting a longest path through the selected logical cell based on the identified longest arrival path and longest propagation path. For each logical cell, the maximum arrival time and maximum propagation delay for each pin of the logical cell are determined based on an evaluation of the logical cell for each two-cycle stimulus in a set of two-cycle stimuli.

The method according to the first aspect enables the identification of a longest path through a cell in an integrated circuit based on data that takes account of both single input switched and multiple input switched stimuli.

In a first implementation form, the method includes repeating acts c)-e) for each input pin and output pin of the selected logical cell.

In a second implementation form, the method includes selecting one or more further logical cells and repeating acts c)-e) for each input pin and output pin of each of the further selected logical cells.

In a third implementation form, identifying the longest arrival path from the output pin O includes identifying a path from the output pin O to an input pin I₁ of the selected logical cell that maximizes a quantity T_{max_arriv}(I₁)+Dₘₐₓ(I₁→O), where T_{max_arriv}(I₁) is the maximum arrival time of the input pin I₁, and Dₘₐₓ(I₁→a) is the maximum propagation delay from I₁ to O.

In a fifth implementation form, identifying a longest arrival path from the start point to the output pin of the selected logical cell includes iteratively a) identifying an output Oᵢ and logical cell that drives the preceding input pin Iᵢ₋₁ on the path, and b) identifying a subsequent input pin Iᵢ of the identified logical cell that maximizes a quantity T_{max_arriv}(Iᵢ)+Dₘₐₓ (Iᵢ→Oᵢ), where T_{max_arriv}(Iᵢ) is the maximum arrival time of the input pin Iᵢ, and Dₘₐₓ (Iᵢ→Oᵢ) is the maximum propagation delay from Iᵢ to Oᵢ.

In a sixth implementation form, the identifying of the longest propagation path from the input pin I includes identifying a path from the input pin I to an output pin O₁ of the selected logical cell that maximizes a quantity T_{max_prop}(I)+Dₘₐₓ (I→O₁) where T_{max_prop}(I) is the maximum propagation time of the input pin I, and Dₘₐₓ (I→O₁) is the maximum propagation delay from I to O₁.

In a seventh implementation form, identifying a longest propagation path from the input pin I includes, iteratively: a) identifying an input pin Iᵢ and logical cell that is driven by the preceding output pin Oᵢ₋₁ on the path, and b) identifying a subsequent output pin Oᵢ of the identified logical cell that maximizes a quantity T_{max_prop}(Iᵢ)+Dₘₐₓ (Iᵢ→Oᵢ), where T_{max_prop}(I) is the maximum propagation time of the input pin Iᵢ, and Dₘₐₓ(Iᵢ→Oᵢ) is the maximum propagation delay from Iᵢ to Oᵢ.

These and other aspects of the present embodiments will be apparent from the embodiments described below.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 shows a schematic diagram of a circuit, according to an example.

FIG. 2 shows a flow diagram of a method 200 for determining propagation delay in a logical cell, according to an example.

FIG. 3 shows a schematic diagram of a circuit, according to an example.

FIG. 4 shows a flow diagram of a method for generating a combined database for a cell library, according to an example.

FIG. 5 shows a flow diagram of a method for extracting a path with a longest delay through an integrated circuit, according to an example.

FIG. 6 shows a flow diagram of a method for timing verification test generation, according to an example.

FIG. 7 shows a schematic diagram of a circuit, according to an example.

FIG. 8 shows a flow diagram of a method for automatic test pattern generation, according to an example.

FIG. 9 is a schematic representation of a data-processing system adapted to carry out embodiments.

### DETAILED DESCRIPTION

Example embodiments are described below in sufficient detail to enable those of ordinary skill in the art to embody and implement the systems and processes herein described. It is important to understand that embodiments may be provided in many alternate forms and should not be construed as limited to the examples set forth herein.

Accordingly, while embodiments may be modified in various ways and take on various alternative forms, specific embodiments thereof are shown in the drawings and described in detail below as examples. There is no intent to limit to the particular forms disclosed. On the contrary, all modifications, equivalents, and alternatives falling within the scope of the appended claims should be included. Elements of the example embodiments are consistently denoted by the same reference numerals throughout the drawings and detailed description where appropriate.

The terminology used herein to describe embodiments is not intended to limit the scope. The articles “a,” “an,” and “the” are singular in that they have a single referent; however, the use of the singular form in the present document should not preclude the presence of more than one referent. In other words, elements referred to in the singular may number one or more, unless the context clearly indicates otherwise. It will be further understood that the terms “comprises,” “comprising,” “includes,” and/or “including,” when used herein, specify the presence of stated features, items, steps, operations, elements, and/or components, but do not preclude the presence or addition of one or more other features, items, steps, operations, elements, components, and/or groups thereof.

References herein to a “design” encompass data describing a microdevice, such as an integrated circuit device or System-On-Chip (SoC) device. However, “design” may also relate, for example, to an individual layer of an integrated circuit device, or portion of a layer. References herein to a “cell” or “logical cell” refer to logical circuit within a design. An “input pattern” or “stimulus” includes an input signal to a cell where the signal includes an input value for each input pin of the cell. The term “cell library” refers to a collection of logical cells that are used in a design. A “cell instance” refers to a particular instance of a logical cell in an actual integrated circuit. “Propagation delay” refers to a measure of the time it takes for a change of input value on a targeted input pin of a cell to propagate to a targeted output pin of the cell.

Unless otherwise defined, all terms including technical and scientific terms used herein are to be interpreted as is customary in the art. It will be further understood that terms in common usage should also be interpreted as is customary in the relevant art and not in an idealized or overly formal sense unless expressly so defined herein.

The methods and systems described herein provide an approach to test generation for timing related defects referred to as timing-verification test generation. Timing-verification test generation provides versatility that allows an ATPG tool to target a delay defect via the longest path under single input switching (SIS) or multiple input switching (MIS) conditions, considering the cell and interconnect delays at different PVT corners and under aging effects, referred to herein collectively as PVTA combinations. This versatility provides that the timing of critical paths is tested under every condition.

Timing-verification test generation has several components. A characterization of the library cells used for the design is performed under different operating conditions and aging effects. For every cell, the cell characterization procedure exhaustively analyzes all the two-cycle input stimuli to find the stimuli that may propagate transitions through the cell, and their propagation delays. This provides that timing information is available to support test generation with maximum path delays.

The library characterization database is combined with timing information obtained from a second source of timing information such as a standard delay format (SDF) file. The SDF file is a data file including timing information for a design. SDF files provide the timing behavior for cell instances used in the design as well as the interconnect delays. In an SDF, two instances of the same cell may have different timing information depending on design characteristics such as load capacitance. However, the SDF only considers single-input switching when characterizing delays. The SDF does not consider cases where multiple inputs of a cell switch together in the same clock cycle.

Users of timing-verification test generation have the freedom to obtain one or more SDF files that are suitable for their application. An SDF file may be generated corresponding to every PVT corner. The procedure for timing-verification test generation enhances the SDF data with timing information obtained by performing cell-level delay characterization for the standard cell library that the design uses. The combined database includes timing information for cases where multiple inputs switch together as well as the effects of operating conditions and aging.

Under timing-verification test generation, delay calculation is applied using the combined timing database to extract the paths with the largest delays. The process of extracting a path starts from two-cycle cell-aware defects, referred to as cell-aware-test 2-time-frame or CAT-2TF defects. A CAT-2TF defect model is a model of a delay defects that occurs in silicon and is based on an actual defect that happens inside a transistor within a standard cell. For every CAT-2TF defect, the longest path through which the CAT-2TF defect may be detected is obtained. This creates a superset of path delay faults, from which a subset that includes the longest paths is selected for test generation.

Given a longest path associated with a CAT-2TF defect, a traditional test generation procedure is first used to produce a test cube that satisfies the basic propagation conditions of the path delay fault. A test cube includes a partially specified input vector where the specified values are sufficient to detect a particular fault or set of faults. The test cube is then expanded into one or more tests that maximize the delay of the path under different conditions by using the timing database. This is an optimization process that involves satisfying additional propagation conditions for cells along the path. The process prefers the cell and its input stimulus that contribute the most to the delay of the path.

The methods described herein may be used to enable the application of the tests produced by timing-verification ATPG in addition to conventional 2-cycle patterns. This enables evaluation of the impact of the timing-verification tests on detecting additional timing related defects that potentially escape from other manufacturing tests.

### Library Characterization

According to examples described herein, library characterization is performed on each cell in a cell library to determine propagation delay. In a first step, all effective two-cycle stimuli are identified for a targeted input/output pin of a cell. A two-cycle stimulus includes two input patterns to the cell. A stimulus may be effective if it satisfies the following two conditions with respect to the targeted input pin and an output pin: Observation condition—there is to be a transition at the targeted output pin; and propagation condition—the transition from the targeted input pin is to propagate to the output pin without being masked by a transition from any other input value.

Herein, a targeted input pin is referred to as the on-path input, and the other input pins are referred to as off-path inputs.

Effective stimuli are categorized into two types: single input switching (SIS) and multiple input switching (MIS). In single input switching (SIS), only the on-path input carries a transition. The off-path inputs hold constant logic values. For unate and primitive gate types such as AND/NAND, OR/NOR gates, the constant logic values are the same as their non-controlling values. As for complex cells such as And-Or-Inverter or XOR/XNOR, there is no fixed non-controlling value, and the constant logic values vary from stimulus to stimulus. For multiple input switching (MIS), off-path inputs also carry transitions while satisfying the propagation condition. To check that the propagation condition is satisfied, the on-path input is held at its initial value while the other inputs are allowed to make the transition. The propagation condition is satisfied if the output does not make a transition until the on-path input changes.

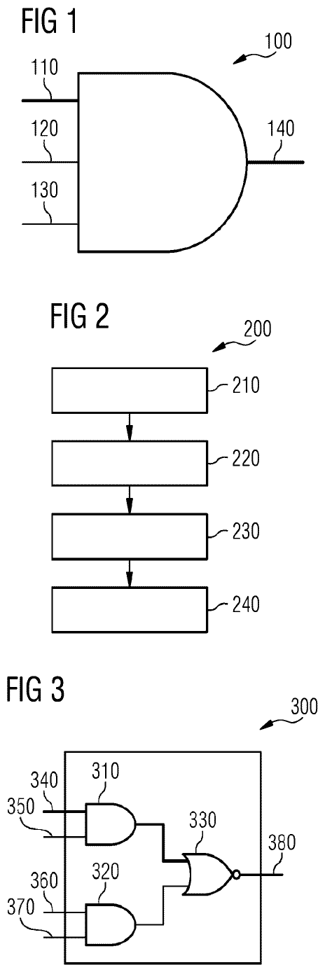

FIG. 1 is a circuit diagram showing a logical cell 100 according to an example. The cell in 100 is an AND gate with three input pins 110, 120, 130 and a single output pin 140. An input pattern including input values to each of the input pins 110, 120, 130 may be applied to the cell 100, and an output signal is observed on the output pin 140. In the example shown in FIG. 1, input pin 110 is the on-path input, and the output pin 140 is the on-path output. Input pins 120, 130 are the off-path inputs.

Table 1 below illustrates an effective two-cycle MIS stimulus for the cell 100. In Table 1, the first row shows the values in the first cycle referred to herein as launch cycle, and the third row shows the values in the second cycle referred to herein as the capture cycle. The second row shows the values when the off-path inputs 120, 130 have changed but the on-path input 110 has not. The rising transition of the on-path input 110 finalizes the transition at the output 140. In other words, the rising transitions on the off-path inputs 120, 130 do not affect the propagation path from the on-path input 110 to the output 140.

TABLE I

| Cyc/Pins | 110 (On-path) | 120 | 130 | 140 (Output) |
|---|---|---|---|---|
| Launch | 0 | 0 [symbol] | 0 [symbol] | 0 |
| Intermediate | 0 [symbol] | 1 | 1 | 0 [symbol] |
| Capture | 1 | 1 | 1 | 1 |

In the example shown in FIG. 1, the propagation condition would not be satisfied in the case where the input signals to inputs 110, 120, 130 makes a falling transition. In this case, after inputs 120, 130 have changed, the output 140 makes a transition, and the change in the on-path input 110 does not propagate to the output 140.

FIG. 2 shows a flow diagram of a method 200 for determining propagation delay in a cell. The method 200 may be repeated for each input/output pin pair treating each pair as the on-path input and output. The method 200 may be implemented in conjunction with the other methods and systems described herein.

At block 210, the method 200 includes identifying an input pin and output pin as the on-path input and output. At block 220, the method includes evaluating a model of the logical cell for each pair of input patterns from a set comprising pairs of input patterns. The model may be a representation of the circuit as an analogue circuit simulation model. Each input pattern includes an input value for each input pin. The evaluation includes, in a first cycle of two cycles, evaluating the logical cell based on the first input pattern and, in the second cycle of the two cycles, evaluating the logical cell based on the second input pattern of the pair of input patterns.

At block 230, the method includes identifying a subset of the set of input patterns. For each pair in the subset, the output value for the on-path output transitions from a first value at the start of the first cycle to a second value, different from the first value, at the end of the second cycle, thus satisfying the observation condition. Further, for each pair in the subset, a transition of an input value for the on-path input from a first value to a second value, different from the first value, during either the first or second cycle, is propagated to the on-path output so that the output value at the end of the second cycle depends on the transition of the input value. Therefore, for each pair in the identified subset, the propagation condition is satisfied.

At block 240, the method includes determining a propagation delay for each pair of input patterns in the subset. The propagation delay may be computed using simulation program with integrated circuit emphasis (SPICE) software or similar. The method 200 may be repeated for both rising and falling transitions of the on-path input.

A maximum propagation delay for effective two-cycle stimuli of a cell may be determined by computing propagation delays according to the method 200. The method 200 may be applied to every cell in a cell library to obtain a complete library characterization.

FIG. 3 shows a circuit diagram of a logical cell 300, according to an example. The cell 300 illustrated in FIG. 3 is a AND-OR-INVERTER including two two-input AND gates 310, 320 followed by a NOR gate 330. In FIG. 3, the on-path input is an input pin 340 of the AND gate 310. The remaining input pins 350, 360, 370 are off-path inputs, and the single output pin 380 is the on-path output.

Table II below shows all the stimuli with a falling transition that propagates from the on-path input 340 to output 380, ranked from the maximum to the minimum propagation delay. In Table II, the propagation delays are normalized based on the minimum delay. Each stimulus in the second column of Table II is represented in a format <ABCD>, where each of A, B, C, D, corresponding to input pins 340, 350, 360, 370, are either F for a falling transition, R for a rising transition, or a constant 0/1 value.

TABLE II

| Rank | Stimulus | Type | Delay |
|---|---|---|---|
| 1 | F1RF | MIS | 1.400 |
| 2 | F1R0 | MIS | 1.369 |
| 3 | F11F | MIS | 1.365 |
| 4 | F110 | SIS | 1.348 |
| 5 | F1RF | MIS | 1.347 |
| 6 | FRF1 | MIS | 1.318 |
| 7 | F1F1 | MIS | 1.289 |
| 8 | F10R | MIS | 1.285 |
| 9 | F1FR | MIS | 1.280 |
| 10 | F101 | SIS | 1.270 |
| 11 | F1FF | MIS | 1.018 |
| 12 | FRFF | MIS | 1.015 |
| 13 | F1F0 | MIS | 1.011 |
| 14 | F10F | MIS | 1.001 |
| 15 | F100 | SIS | 1 |

The maximum propagation delay by the MIS stimulus <F1RF> introduces a 40% greater delay compared to the minimum case by the SIS stimulus (F100). Different SIS stimuli also have significant delay differences (e.g., the SIS stimulus <F101> ranked at the 4th place can introduce around 35% more delay than the minimum delay). The result indicates that the timing information related to MIS stimuli should not be neglected, and relying on SIS information may not yield the maximum path delays.

In further tests, a percentage difference p_{diff} between the largest propagation delay for any stimulus, dₘₐₓ, and smallest propagation delay for any stimulus, dₘᵢₙ was measured for all the NOR cells, and all the AND-OR-INVERTER and AND-OR cells in a commercially available cell library. Considering all possible stimuli and on-path input and outputs, in the NOR cells, MIS stimuli were observed to cause the maximum propagation delay in 80% of cases, and the maximum p_{diff} for NOR cells was 5%. In the AND-OR-INVERTER and AND-OR cells, MIS stimuli caused the maximum propagation delay in 81% of cases, and the maximum p_{diff} was 60%. Further, around 30% of MIS stimuli in the AND-OR-INVERTER and AND-OR cells induced a propagation delay of 10% or longer compared to the minimum delay.

Considering all the library characterization results, two trends were observed: First, the maximum delay difference is higher for more complex cells; second, in most cases, MIS stimuli result in the maximum propagation delay.

The method 200 may be repeated for every cell in a cell library to obtain a library characterization. However, the timing information is the same for every instance of a cell in the actual design. An SDF file provides timing information per instance of a cell in the design. Instances of the same library cell may have distinct timing information in the SDF file based on characteristics such as load capacitance and drive strength that change from instance to instance. However, the SDF file for the design has equal delays for different SIS stimuli associated with the same on-path input and output of an instance. In addition, the SDF file does not include MIS stimuli as discussed earlier.

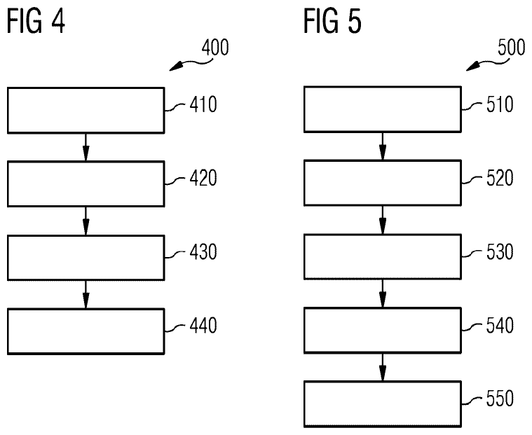

FIG. 4 is a block diagram showing a method 400 for generating a combined database. The combined database utilizes both the instance-dependent information from the SDF file and the extensive data provided by the cell library characterization. For each instance, all stimuli from both sources are considered. The method 400 may be used in conjunction with the other methods described herein, and, for example, the method 200.

At block 410, the method 400 includes accessing a cell library including a plurality of cells for a design. At block 420, the method 400 includes determining, for each cell in the cell library, propagation delays for every pair of input and output pins of the cell. According to examples, propagation delays may be determined using the method 200, previously described. At block 430, the method includes accessing, for each instance of each cell, a standard delay format (SDF) file including timing information for the instance. At block 440, the method 400 includes combining the timing information from the SDF and propagation delays for the cell to obtain a combined database. According to examples, combining the timing information and propagation delays includes adjusting propagation delays based on the timing information, to obtain propagation delays for the cell instances.

In some examples, one of timing information values in the SDF file may be used as a baseline, and propagation delays from the library characterization are adjusted to the SDF baseline. When multiple SDF files are provided to cover different PVTA combinations, the adjustment may be repeated for every combination. This will apply when there are no aging effects. With aging effects in a PVT combination, the SDF file corresponding to the PVT corner may be used, and the cell characterization data for the PVTA combination may be combined with the data from the SDF file.

According to examples, each on-path input and output pair of a cell is considered separately for adjustment. Considering the propagation delays obtained from the cell characterization, all the SIS and MIS stimuli are sorted from the maximum to the minimum propagation delay: d₀, d₁, d₂, . . . dₙ₋₁. Let the minimum SIS delay be dᵢ. Considering the SDF file, let the corresponding delay of the same SIS stimulus be r₀. When the minimum SIS stimulus is added to the SDF data, its delay is adjusted by r₀/dᵢ. The same adjustment may be applied to all the stimuli. Thus, dⱼ is replaced with dⱼ*T₀/dᵢ.

Table III below illustrates adjustment for a 3-input AND cell, such as the AND cell 100 shown in FIG. 1, with on-path input 110 and output 140. The first column of Table III is an index numeral for the different stimuli being considered. The second column indicates the stimulus. The third column indicates the type of stimulus, either SIS or MIS. The fourth column provides the propagation delay from the library characterization (units are arbitrary). The fifth column includes the adjusted delay.

TABLE III

| | | | | Adjusted |
|---|---|---|---|---|
| Index | Stimulus | Type | Delay | delay |
| 1 | RRR | MIS | 12 | 1.2 * r₀ |
| 2 | RR1 | MIS | 11 | 1.1 * r₀ |
| 3 | R11 | SIS | 10 | r₀ |
| 4 | R1R | MIS | 8 | 0.8 * r₀ |

The third stimulus is the only SIS stimulus and is selected to be the base SIS stimulus to perform the delay adjustments. The timing information obtained from the SDF file for the SIS stimulus is r₀. For 1≤j≤4, the adjusted delay of the jth stimulus is dⱼ*r₀/dᵢ. The adjusted delay of the 3rd stimulus is equal to r₀ (e.g., the value from the SDF file), and all the other delays are adjusted based on the delay ratios.

### Longest Path Extraction

FIG. 5 shows a block diagram of a method 500 for extracting a path with a longest delay time through an integrated circuit. The method 500 may be used in conjunction with other methods and systems described herein.

At block 510, the method 500 includes obtaining a dataset for the integrated circuit. The dataset includes a maximum arrival time and maximum propagation delay for each pin in the integrated circuit and is generated based on a static path delay computation using data from the combined database (e.g., maximum propagation delay data for each cell, obtained from evaluation of each cell for two-cycle input stimuli). A static path delay may be determined by adding a maximum propagation delay for every cell in a design as well as the interconnect delays for the lines along the path. This computation does not attempt to justify any values. Using the combined database, it uses the stimuli with the maximum propagation delay for every cell without checking whether the stimuli can be justified.

At block 520, the method 500 includes selecting a logical cell in the integrated circuit. At block 530, the method 500 includes identifying a longest arrival path from a start point in the integrated circuit to an output pin, O, of the selected logical cell based on the dataset. The start point may be a primary input of the integrated circuit or a scan cell.

In examples, identifying the longest arrival path from the output pin O includes identifying a path from the output pin O to an input pin I₁ of the selected logical cell that: a) maximizes a quantity T_{max_arriv}(I₁)+Dₘₐₓ(I₁→O) where T_{max_arriv}(I₁) is the maximum arrival time of the input pin I₁ and Dₘₐₓ (I₁→O) is the maximum propagation delay from I₁ to O; and b) is associated with a transition on the output, O. After the input pin is selected, the output pin that drives it is identified, and the process is repeated for the logical cell associated with that output pin. This repeats until a scan cell or primary input is reached.

At block 540, the method 500 includes identifying a longest propagation path from an input pin, I, of the selected logical cell to an end point in the integrated circuit. The end point may be a primary output of the integrated circuit or a scan cell.

In examples, identifying the longest propagation path from the input pin I includes identifying a path from the input pin I to an output pin O₁ of the selected logical cell that: a) maximizes a quantity T_{max_prop}(I)+Dₘₐₓ (I→O₁) where T_{max_prop}(I) is the maximum propagation time of the input pin I and Dₘₐₓ (I→O₁) is the maximum propagation delay from I to O₁; and b) the output O₁ is associated with a transition on the input I. After the output pin that satisfies these conditions is identified, the process repeats until a scan cell or primary output is reached. Depending on the cell type of an instance, both rising and falling transitions may be considered for the output to maximize the propagation delay.

At block 550, the longest path through the selected logic is extracted based on the identified longest arrival path and longest propagation path.

### Timing Verification Test Generation

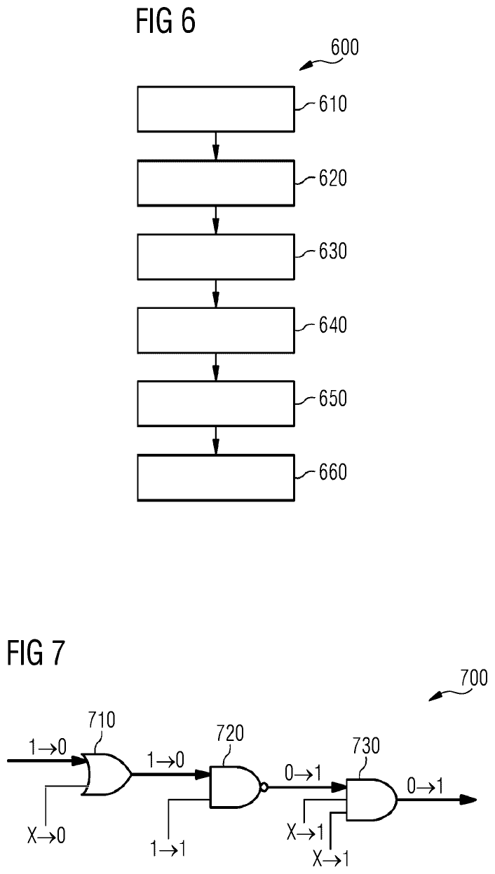

FIG. 6 is a block diagram of a method for timing verification test generation, according to an example. The method 600 may be implemented in conjunction with other methods and systems described herein. The method 600 depicts timing verification test generation for a single PVTA combination. At block 610, the method 600 includes obtaining a design for an integrated circuit. At block 620, the method 600 includes obtaining a combined database of propagation delays for each instance of each cell in the cell library of the design, for example, using the method 400 previously described. At block 630, a static path delay for each pin in the design is determined from a maximum arrival time at the pin and propagation delay from the pin, based on the combined database. At block 640, CAT-2TF defects with slacks below a user defined threshold are identified and stored in a list. Slack refers to the difference between the actual clock period and the propagation delay of a path. At block 650, longest paths through each CAT-2TF defect in the list are extracted, for example, using the method 500 previously described. In some cases, two different CAT-2TF defects in the list may result in the same longest path. To avoid duplicated paths in the set of extracted paths, each newly extracted path may be compared to paths extracted earlier, and checked to determine whether the path has already been extracted. This check may be sped up by associating a unique numerical identifier with every path. At block 660, timing verification ATPG is applied to every extracted path for a CAT-2TF defect.

Timing-verification ATPG may be applied to every extracted path for a CAT-2TF defect. Given a path p, a path-delay ATPG framework starts by deriving the assignments necessary for a strong non-robust test for p. These assignments include a transition at the source of the path, and a non-controlling value on every off-path input during the second clock cycle of the test. The set of assignments for p is denoted by A(p). A path-delay ATPG is used for generating a test cube for p that satisfies the assignments in A(p). Once a test cube is generated, an arrival time analysis may be performed for on-path and off-path inputs to determine whether only SIS stimuli, or both SIS and MIS stimuli, are needed for every cell. This is followed by an optimization process applied to maximize the delay of the path. Additional values are specified based on the cells along the path p having off-path inputs that have unspecified values.

The stimuli from the combined timing database that are consistent with the assignments in A(p) are found for every cell. The stimuli are sorted by descending order of their contribution to the delay of the path. Considering the stimuli in this order, the stimulus at the top of the list is added to A(p), and test generation attempts to produce a new test cube based on A(p).

FIG. 7 depicts a path, p, through a circuit 700, according to an example. The circuit 700 includes a two input OR gate 710 a two input NAND gate 720 and a two three input AND gate 730. The path p is indicated by arrows. FIG. 7 depicts a transition at the source of the path p and non-controlling values on every off-path input in the second clock cycle. Satisfying these assignments leaves unspecified values on off-path inputs at the OR gate 710 and AND gate 730 as indicated by the variable X in FIG. 7. This determines the set A(p) of possible assignments for path p. The cell stimuli consistent with assignments in the set of assignments A(p) are depicted in Table IV below. For each cell, the stimuli in table IV are shown in descending order by delay in the fourth column.

TABLE IV

| Stimulus | Cell | Type | Delay | Extra |
|---|---|---|---|---|
| RRR | 730 | MIS | 10 | 4 |
| RR1 | 730 | MIS | 8 | 2 |
| R11 | 730 | SIS | 7 | 1 |
| R1R | 730 | MIS | 6 | 0 |
| FF | 710 | MIS | 7 | 3 |
| F0 | 710 | SIS | 4 | 0 |

Even if the unspecified values are filled randomly, the AND cell 730 will have delay of 6 units, the smallest delay consistent with A(p). In Table IV, the fifth column indicates the extra delay on top of the smallest delay consistent with A(p) for each cell. Table V below shows a re-ordering of Table IV based on the extra delay indicated in the fifth column of Table IV.

TABLE V

| Stimulus | Cell | Type | Extra |
|---|---|---|---|
| RRR | 730 | MIS | 4 |
| FF | 710 | MIS | 3 |
| RR1 | 730 | MIS | 2 |
| R11 | 730 | SIS | 1 |
| R1R | 730 | MIS | 0 |
| F0 | 710 | SIS | 0 |

During test generation, stimuli are ordered according to the ordering in Table V. Thus, the additional justification will first consider the off-path inputs of the AND cell 730 for a possible MIS stimulus (RRR). It will then consider the OR cell 710 with the stimulus (F F).

As new test cubes are computed and A(p) is updated, the stimuli consistent with A(p) are found and sorted. A backtrack limit is used for every stimulus and every cell to limit the runtime. Test generation terminates when the list of stimuli consistent with A(p), and have not been considered is empty.

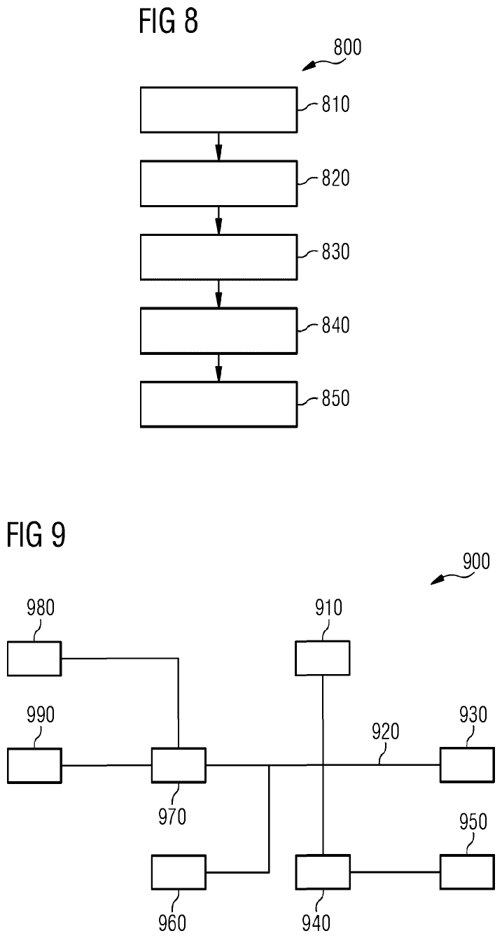

FIG. 8 depicts a method 800 for timing-verification ATPG, according to an example. The method 800 may be used in conjunction with the other methods and systems described herein. At block 810, the method 800 includes deriving a set of assignments A(p), for performing a strong non-robust test for a path p. At block 820, the method 800 includes generating a test cube for A(p). If a test cube cannot be generated for A(p), the method 800 terminates. Let S denote the set of stimuli consistent with A(p). At block 830, the method 800 includes identifying for each cell, a stimulus, s₀ in S, with a lowest delay, and determining a difference, xᵢ, between stimulus sᵢ and s₀, for each stimulus sᵢ for the cell in S. At block 840, the method 800 includes ordering the stimuli in S based on the determined differences. At block 850, the method 800 includes, repeating until the set S is empty: a) select the stimulus sᵢ at the top of S and removing sᵢ from S; b) adding sᵢ to A(p); and c) generating a new test cube for A(p). If a new test cube is generated, all the stimuli that conflict with A(p) are removed from S. Otherwise, sᵢ is removed from A(p). At the end of method 800, the resulting test cube is the new test cube for path p.

The timing-verification test generation procedure depicted in FIGS. 6 to 8 may be repeated for multiple PVTA combinations of a design to create a superset of timing-verification test patterns so that the design may be tested more comprehensively. Each PVTA combination requires a separate SDF file, and the library characterization is performed for that combination. Some patterns may be shared by different PVTA combinations. When the device under test (DUT) is subjected to a specific PVTA combination on an ATE, the corresponding subset of timing-verification test patterns are applied to detect defects that may escape from other PVTA combinations.

The methods described herein may be applied in conjunction with other manufacturing tests and cell-aware testing. The defects detected by the timing-verification tests are unique and not detected by other tests. The units that failed timing-verification tests may be analyzed for diagnosis purpose to determine the cause of the failure.

FIG. 9 illustrates an example of a data processing system in which an embodiment of the present disclosure may be implemented (e.g., to perform the methods of the embodiments as described herein). The data processing system 900 includes a processor 910 connected to a local system bus 920. The local system bus 920 connects the processor 910 to a main memory 930 and graphics display adaptor 940, which may be connected to a display 950. The data processing system 900 may communicate with other systems via a wireless user interface adapter connected to the local system bus 920, or via a wired network (e.g., to a local area network). Additional memory 960 may also be connected via the local system bus 920.

A suitable adaptor, such as wireless user interface adapter 970, for other peripheral devices, such as a keyboard 980 and mouse 990, or other pointing device, allows the user to provide input to the data processing system. Other peripheral devices may include one or more I/O controllers such as USB controllers, Bluetooth controllers, and/or dedicated audio controllers (e.g., connected to speakers and/or microphones). Various peripherals may be connected to the USB controller (e.g., via various USB ports) including input devices (e.g., keyboard, mouse, touch screen, trackball, camera, microphone, scanners), output devices (e.g., printers, speakers), or any other type of device that is operative to provide inputs or receive outputs from the data processing system.

Many devices referred to as input devices or output devices may both provide inputs and receive outputs of communications with the data processing system. Further, other peripheral hardware connected to the I/O controllers may include any type of device, machine, or component that is configured to communicate with a data processing system.

An operating system included in the data processing system enables an output from the system to be displayed to the user on the display and the user to interact with the system. Examples of operating systems that may be used in a data processing system may include Microsoft Windows™, Linux™, UNIX™, iOS™, and Android™ operating systems.

In addition, the data processing system 900 may be implemented as or in a networked environment, distributed system environment, virtual machines in a virtual machine architecture, and/or cloud environment. For example, the processor and associated components may correspond to a virtual machine executing in a virtual machine environment of one or more servers. Examples of virtual machine architectures include VMware ESCi, Microsoft Hyper-V, Xen, and KVM.

Those of ordinary skill in the art will appreciate that the hardware depicted for the data processing system 900 may vary for particular implementations. For example, the data processing system 900 in this example may correspond to a computer, workstation, and/or a server. However, alternative embodiments of a data processing system may be configured with corresponding or alternative components such as in the form of a mobile phone, tablet, controller board, or any other system that is operative to process data and carry out functionality and features described herein associated with the operation of a data processing system, computer, processor, and/or a controller discussed herein. The depicted example is provided for the purpose of explanation only and is not meant to imply architectural limitations with respect to the present disclosure.

The data processing system 900 may be connected to the network (not a part of data processing system 900), which may be any public or private data processing system network or combination of networks, as known to those of skill in the art, including the Internet. The data processing system 900 may communicate over the network with one or more other data processing systems such as a server (also not part of the data processing system 900). However, an alternative data processing system may correspond to a plurality of data processing systems implemented as part of a distributed system in which processors associated with several data processing systems may be in communication via one or more network connections and may collectively perform tasks described as being performed by a single data processing system. Thus, when referring to a data processing system, such a system may be implemented across several data processing systems organized in a distributed system in communication with each other via a network.

The data processing system 900 is adapted to carry out the methods in accordance with the embodiments described herein. For example, the keyboard 980 and the mouse 990 may function as a user input device for receiving information from the user, the processor 910 may be adapted to carry out the acts of the method, and the display 950 may be adapted to display a particular view to the user. A computer product including instructions that, when run on a computer, such as the data processing system 900, may be provided to cause the computer to execute the acts of the methods of the embodiments outlined above.

The present disclosure is described with reference to flow charts and/or block diagrams of the method, devices, and systems according to examples of the present disclosure. Although the flow diagrams described above show a specific order of execution, the order of execution may differ from that which is depicted. Blocks described in relation to one flow chart may be combined with those of another flow chart. In some examples, some blocks of the flow diagrams may not be necessary and/or additional blocks may be added.

The present inventions may be embodied in other specific apparatus and/or methods. The described embodiments are to be considered in all respects as illustrative and not restrictive. In particular, the scope of the invention is indicated by the appended claims rather than by the description and figures herein. All changes that come within the meaning and range of equivalency of the claims are to be embraced within their scope.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method for extracting a path with a longest delay time through an integrated circuit, the method being computer-implemented and comprising:
obtaining a dataset for the integrated circuit, the dataset comprising a maximum arrival time and a maximum propagation delay for each pin in the integrated circuit;
selecting a logical cell in the integrated circuit;
identifying a longest arrival path from a start point in the integrated circuit to an output pin O of the selected logical cell based on the dataset;
identifying a longest propagation path from an input pin of the selected logical cell to an end point in the integrated circuit; and
extracting a longest path through the selected logical cell based on the identified longest arrival path and longest propagation path,
wherein, for each logical cell, the maximum arrival time and the maximum propagation delay for each pin of the logical cell are determined based on an evaluation of the logical cell for each two-cycle stimulus in a set of two-cycle stimuli.

2. The method of claim 1, further comprising repeating the identifying of the longest arrival path, the identifying of the longest propagation path, and the extracting for each input and output pin of the selected logical cell.

3. The method of claim 1, further comprising selecting one or more further logical cells and repeating the identifying of the longest arrival path, the identifying of the longest propagation path, and the extracting for each input and output pin of each of the further selected logical cells.

4. The method of claim 1, wherein identifying the longest arrival path from the output pin O, comprises identifying a path from the output pin O to an input pin I₁ of the selected logical cell that maximizes a quantity
T_{max_arriv}(I₁)+Dₘₐₓ(I₁→O), and
wherein T_{max_arriv}(I₁) is the maximum arrival time of the input pin, and Dₘₐₓ(I₁→O) is the maximum propagation delay from I₁ to O.

5. The method of claim 4, wherein identifying the longest arrival path from the start point to the output pin of the selected logical cell comprises iteratively:
identifying an output Oᵢ and logical cell that drive the preceding input pin Iₜ₋₁ on the path; and
identifying a subsequent input pin Iᵢ of the identified logical cell that maximizes a quantity T_{max_arriv}(Iᵢ)+Dₘₐₓ(Iᵢ→Oᵢ), and
wherein T_{max_arriv}(Iᵢ) is the maximum arrival time of the input pin lᵢ, and Dₘₐₓ(Iᵢ→Oᵢ) is the maximum propagation delay from Iᵢ to Oᵢ

6. The method of claim 1, wherein identifying the longest propagation path from the input pin I comprises identifying a path from the input pin I to an output pin O₁ of the selected logical cell that maximizes a quantity
T_{max_prop}(I)+Dₘₐₓ(I→O₁), and
wherein T_{max_prop}(I) is the maximum propagation time of the input pin L, and Dₘₐₓ(I→O₁) is the maximum propagation delay from I to O₁.

7. The method of claim 6, wherein identifying the longest propagation path from the input pin I comprises iteratively:
identifying an input pin Iᵢ and logical cell that are driven by the preceding output pin Oᵢ₋₁ on the path; and
identifying a subsequent output pin Oᵢ of the identified logical cell that maximizes a quantity
T_{max_prop}(Iᵢ)+Dₘₐₓ(Iᵢ→Oᵢ),
wherein T_{max_prop}(I) is the maximum propagation time of the input pin Iᵢ, and Dₘₐₓ (Iᵢ→Oᵢ) is the maximum propagation delay from Iᵢ to Oᵢ.

8. The method of claim 1, wherein obtaining the dataset comprises:
accessing a cell library comprising the logical cells of the integrated circuit; and
determining, for each logical cell in the cell library, propagation delays for every pair of input and output pins of the logical cell based on an evaluation of two-cycle single input switched stimuli and multiple input switched stimuli.

9. The method of claim 8, further comprising:
accessing a stored data file comprising interconnect delay information and timing information for an instance of a logical cell in the integrated circuit; and
adjusting the propagation delays of each input pin and output pin of the logical cell, based on the timing information, to obtain a propagation delay of each input pin and output pin of the instance.

10. The method of claim 1, wherein determining the maximum propagation delay and the maximum arrival time for each pin comprises determining a static path delay for each path through the pin.

11. A computer-implemented method comprising:
obtaining a design for an integrated circuit;
identifying one or more CAT-2TF defects with slacks below a pre-defined threshold; and
for each of the identified one or more CAT-2TF defects, applying a method for extracting a path with a longest delay time through the integrated circuit, to extract one or more longest paths through the respective CAT-2TF defect, the method for extracting the path with the longest delay time through the integrated circuit comprising:
obtaining a dataset for the integrated circuit, the dataset comprising a maximum arrival time and a maximum propagation delay for each pin in the integrated circuit;
selecting a logical cell in the integrated circuit;
identifying a longest arrival path from a start point in the integrated circuit to an output pin of the selected logical cell based on the dataset;
identifying a longest propagation path from an input pin of the selected logical cell to an end point in the integrated circuit; and
extracting a longest path through the selected logical cell based on the identified longest arrival path and longest propagation path,
wherein, for each logical cell, the maximum arrival time and the maximum propagation delay for each pin of the logical cell are determined based on an evaluation of the logical cell for each two-cycle stimulus in a set of two-cycle stimuli.

12. The method of claim 11, further comprising generating, for each of the one or more identified CAT-2TF defects, a test cube, based on the extracted one or more longest paths through the CAT-2TF defect.

13. The method of claim 12, wherein generating the test cube comprises:
determining a set of assignments for performing a strong non-robust test for a path;
generating an initial test cube for the set of assignments;
identifying a set of stimuli consistent with the set of assignments;
identifying, for each cell on the path, a stimulus s₀ with a minimum delay;
determining a difference between stimulus sᵢ and s₀, for each stimulus sᵢ for the cell; and
ordering the set of stimuli based on the determined difference.

14. The method of claim 13, further comprising:
identifying a stimulus s with greatest difference based on the ordering of the set of stimuli;
removing the stimulus s from the set of stimuli;
adding the stimulus s to the set of assignments; and
generating a modified test cube for the set of assignments.

15. A data processing system comprising:
a processor and a memory, the memory comprising instructions that, when executed by the processor, cause the processor to extract a path with a longest delay time through an integrated circuit, the extraction of the path with the longest delay time through the integrated circuit comprising:
obtainment of a dataset for the integrated circuit, the dataset comprising a maximum arrival time and a maximum propagation delay for each pin in the integrated circuit;
selection of a logical cell in the integrated circuit;
identification of a longest arrival path from a start point in the integrated circuit to an output pin of the selected logical cell based on the dataset;
identification of a longest propagation path from an input pin of the selected logical cell to an end point in the integrated circuit; and
extraction of a longest path through the selected logical cell based on the identified longest arrival path and longest propagation path,
wherein, for each logical cell, the maximum arrival time and the maximum propagation delay for each pin of the logical cell are determined based on an evaluation of the logical cell for each two-cycle stimulus in a set of two-cycle stimuli.
